(19) United States
(12) Patent Application Publication
(10) Pub. No.: US 2003/0042883 A1
(43) Pub. Date: Mar. 6, 2003

(54) Electrical contact spring probe with RF shielding

(76) Inventors: William E. Thurston, Kansas City, MO (US); David W. Henry, Liberty, MO (US)

Correspondence Address: Wm. Bruce Day, SWANSON MIDGLEY, LLC, Suite 400, 2420 Pershing Road, Kansas City, MO, 64108, US

(21) Appl. No.: 09/941,076

(22) Filed: Aug. 28, 2001

(51) Int. Cl. G01R 31/02

(52) U.S. Cl. 324/72.5

(57) ABSTRACT

An electrical contact spring probe for testing circuit continuity attaches to the end of a shielded cable for RF (radio frequency) transmission. The probe has a collapsible shield surrounding a contact plunger to prevent leakage of RF energy to or from neighboring circuit points.

### FIELD OF THE INVENTION

This invention relates to electrical contact spring probes used in the circuit testing industry and particularly to such probes involving radio frequency transmissions.

### BACKGROUND OF THE INVENTION

Electrical contact spring probes are used in a variety of electrical connections including use in custom connectors, test sockets, and interfaces for a broad range of industries including telecommunications, medical/dental, automotive, connectors, ATE component testing, computer, security, aerospace, military, and other specialized applications. Spring contact probes are often quite small and may be densely packed with center to center spacing as little as 0.010″. Electrical interference between contact sites is to be avoided and as a result, various shielding measures have been taken to insure an interference free connection.

The present invention is directed to a shielded electrical contact probe which consists of an RF shield surrounding a probe plunger so that RF energy does not leak from the probe assembly to or from neighboring sites.

### OBJECTS OF THE INVENTION

The objects of the present invention are:

a) to provide a probe assembly including a shield for preventing leaking of RF energy to/from receiving sites;

b) to provide such a probe assembly including a resilient shield able to withstand up to 250,000 cycles;

c) to provide such a probe assembly having an ability to function and prevent leakage of RF energy at high bandwidth emissions;

d) to provide such a probe assembly able to function for sustained periods at high cycle speeds of test equipment; and

e) to provide such a probe assembly which is well suited for the intended purpose and low in cost.

Other objects and advantages of the present invention will become apparent from the following description taken in connection with the drawings.

### DESCRIPTION OF THE DRAWINGS

FIG. 1 is an elevational view of a coaxial cable, probe and shield in disassembled relation.

FIG. 2 is an elevational view of a coaxial cable, probe and shield in assembled relation.

### DESCRIPTION OF THE PREFERRED AND ALTERNATE EMBODIMENTS

As required, detailed embodiments of the present invention are disclosed herein, however, it is to be understood that the disclosed embodiments are merely exemplary of the invention which may be embodied in various forms. Therefore, specific structural and functional details disclosed herein are not to be interpreted as limiting, but merely as a basis for the claims and as a representative basis for one teaching skilled in the art to variously employ the present invention in virtually any appropriately detailed structure.

Referring to the drawings in more detail, the reference numeral 1 refers to a shielded probe assembly which attaches to a coaxial cable 2. The probe assembly 1 has a shield 4 therearound to prevent the leakage of RF energy to or from electrical contact sites other than the site directly engaged by the probe assembly 1.

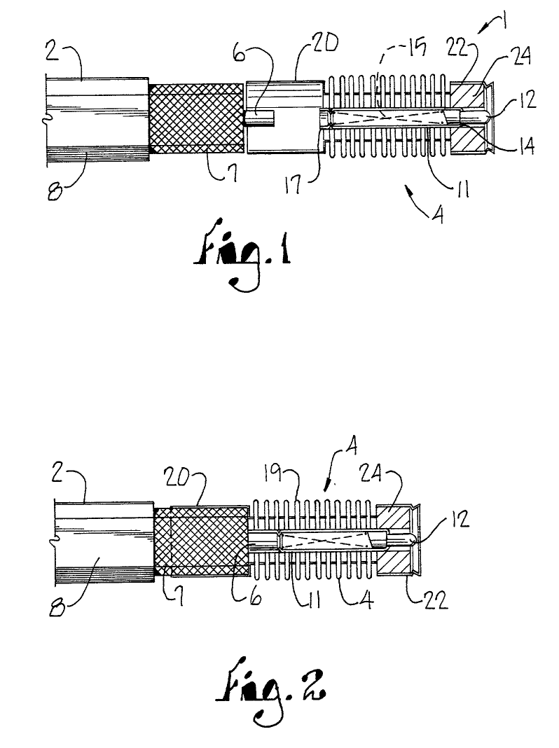

In more detail, the coaxial cable 2 is of typical construction and includes a conductor 6, braided shield 7 and outer sheath 8. To prepare the cable 2 for installation of the probe assembly 1, the cable is cut back to expose the conductor 6, then cut back further to expose the braided shield 7, generally as shown in FIG. 1.

The probe assembly 1 uses a barrel 11 with a plunger 12 extending therefrom through a contact end 14. An internal spring 15, such as a coil spring, is contained within the barrel 11 and biases the plunger 12 to an extended position. The plunger 12 is retained within the barrel 11 by crimping, dimpling, or the like. The barrel 11 has a lead end 17 which is open to receive the conductor 6 of the coaxial cable 2. Preferably, the barrel lead end 17 is sized to snugly receive the conductor 6. The site engagement tip of the plunger 12 may be of various configurations including ball tip, star tip, chisel tip or other engagement tip forms as is well known in the art.

The shield 4 may be of various RF shielding forms and materials, a key requirement of which is that the shield 4 be resilient and able to withstand high speed flexing over extended periods of time. A suitable shield is a metal bellows form of thin wall ductile nickel alloy of the type shown in the drawings, yet it is foreseen that other bellows forms or other shielding forms such as of telescoping sections or of other flexible material may be advantageously used. The exemplary shield 4 is a single piece and is unitary so as to conceal the probe. It has a middle bellows section 19 and an attachment end 20 of smooth tubular form sized appropriately to the diameter of the braided shield 7 of the coaxial cable 2 for snug, slide-on fit. A contact end 22 of the shield 4 spaced oppositely from the attachment end 20 is also of smooth tubular form and into which is inserted an insulator end piece 24. The insulator end piece 24 may be formed of Teflon or other dielectric material. An axial bore through the insulator end piece 24 is sized to snugly receive the contact end 14 of the probe barrel 11 and is of an appropriate thickness so that the plunger 12 extends slightly beyond the end of the insulator end piece 24. The insulator end piece 24 is secured to the contact end 22 of the shield 4 as by crimping. The end piece 24 serves as a guide for the plunger 12.

The probe assembly 1, consisting of the barrel 11 with plunger 12 and the shield 4 is assembled to form a unitary structure and is then attached to the end of a coaxial cable 2 as described; that is, the cable end is stripped and the cable conductor 6 is inserted into the lead end 17 of the barrel 11 and is attached as by crimping for electrical contact. The attachment end 20 is then secured to the cable braided shield 7 as by soldering so that the probe assembly 1 and coaxial cable 2 are positively joined. The device may be provided as a cabled assembly to a user. The probe assembly 1 is useful in situations where closely neighboring sites for tests or operational connection need to be shielded from the introduction of RF energy or emission of RF energy.

What is claimed and desired to be protected by Letters Patent is:

1. An RF shielded electrical contact probe comprising:
a) a probe having a barrel with a spring biased plunger extending from a barrel contact end and a barrel lead end open to receive a conductor of a coaxial cable; and
b) a unitary RF shield surrounding said probe through which said plunger reciprocally extends for contact with a test site, the shield being resilient and biased to an extended position so that a terminus of said RF shield surrounds said test site as said plunger contacts same in order to prevent leakage of RF energy to/from neighboring sites.

2. The RF shielded electrical contact probe set forth in claim 1 wherein said shield is a metal bellows form.

3. The RF shielded electrical contact probe set forth in claim 1 wherein said bellows has an open end sized to receive said coaxial cable including the insulator surrounding said cable, with said bellows open end crimped about said cable insulator to attach said test probe to said coaxial cable.

4. The RF shielded electrical contact probe set forth in claim 1 including an insulator terminus is secured within said shield at a shield contact end so that said shielded electrical contact test probe is attachable to said coaxial cable as a unit consisting of said probe and said shield.

5. An assembly for contacting circuit sites receiving or emitting RF energy comprising:
a) a coaxial cable having a conductor surrounded by an insulator;
b) a probe having a barrel with a spring biased plunger extending from a contact end and a lead end open to receive the conductor of said coaxial cable; and
c) a single piece RF shield surrounding said probe and terminating in an insulator terminus through which said plunger reciprocally extends for contact with a site, the shield being a resilient metal bellows biased to an outward position so that said insulator terminus surrounds said site as said plunger contacts same in order to prevent leakage of RF energy to/from neighboring sites.
